(19) United States
(12) Patent Application Publication
(10) Pub. No.: US 2006/0279297 A1
(43) Pub. Date: Dec. 14, 2006

(54) Contactless area testing apparatus and method utilizing device switching

(76) Inventors: Michael J. Nystrom, San Jose, CA (US); David T. Dutton, San Jose, CA (US); Gloria E. Hofler, Sunnyvale, CA (US)

Correspondence Address: AGILENT TECHNOLOGIES INC., INTELLECTUAL PROPERTY ADMINISTRATION, M/S DU404, P.O. BOX 7599, LOVELAND, CO, 80537-0599, US

(21) Appl. No.: 11/150,548

(22) Filed: Jun. 10, 2005

(51) Int. Cl. G01R 31/02

(52) U.S. Cl. 324/754

(57) ABSTRACT

A probe is locatable adjacent a selected region of a device under test (DUT), the selected region having a plurality of contacts. A generator is capable of establishing a plume of a ionized gas between the probe and the selected region of the DUT, the plume having sufficient cross-sectional area and electrical conductivity to complete an electrical connection between the probe and the plurality of contacts.

### CROSS-REFERENCE TO RELATED APPLICATIONS

This application claims priority from co-pending U.S. patent application Ser. No. 11/020,337 naming David T. Dutton et al.; U.S. patent application Ser. No. 11/020,725 naming Michael J. Nystrom et al., and U.S. patent application Ser. No. 11/021,602 also naming Michael J. Nystrom et al., all filed on Dec. 23, 2004, and all assigned to Agilent Technologies, Inc., the assignee of this application. The entire disclosures of said co-pending applications are hereby incorporated by reference.

### BACKGROUND

There are many instances where it is desirable to subject a device under test (DUT) to measurements of its various properties without physically contacting the DUT. For example, it may be necessary to test the electrical resistance of fragile semiconductor material, or test the conductivity of an inaccessible region of a printed circuit board (PCB), or test the thin film circuitry of an organic light emitting diode (OLED) flat panel display in its delicate image producing area. See, for example, U.S. Pat. No. 6,191,433 granted to Roitman et al. on Feb. 20, 2001 and also assigned to Agilent Technologies, Inc.

In an OLED flat panel display pixel brightness is controlled with a current signal, instead of being controlled with a voltage signal as is done in an LCD display. Thus an OLED flat panel display has at least one additional transistor in each of its pixel drive circuits. In an LCD display a voltage applied to a capacitor in a pixel drive circuit must be measured. In an OLED flat panel display, the current flowing through the additional transistor in the pixel drive circuit must be measured. However, at the stage in the fabrication process of the OLED flat panel display where it is best to test the pixel drive circuit, only two of its three terminals are connected.

Techniques are available for measuring the voltage in a pixel drive circuit of an LCD display without contacting the active area of the display in the middle where the image is formed. Contact may be made with the periphery of the LCD display and a probe near the surface of the active area of the LCD display can sense a voltage in the pixel drive circuit. An electron beam can be used to image the surface, and voltage differences will show up on the surface of the active area of the display as contrast differences.

Measuring the current in a pixel drive circuit of an OLED flat panel display is a more difficult proposition. One technique requires the addition of a capacitor in the pixel drive circuit and measurement of the charging of the capacitor. However, this adds complexity and cost to the pixel circuit since this part of the pixel drive circuit will not be used after testing. The addition of a capacitor in the pixel drive circuit also undesirable utilizes prime real estate. A second approach uses an electron beam as a contactless probe, but this requires placing the OLED flat panel display in a vacuum chamber, so that testing is expensive and time consuming.

### SUMMARY

In accordance with an embodiment of the invention, a contactless testing apparatus includes a probe locatable adjacent a selected region of a device under test (DUT), the selected region having a plurality of contacts. The apparatus further includes a generator capable of establishing a plume of ionized gas between the probe and the selected region of the DUT having sufficient cross-sectional area and electrical conductivity to complete an electrical connection between the probe and the plurality of contacts.

In accordance with another embodiment of the invention a contactless testing method includes the initial step of generating a plume of ionized gas between a probe and a selected region of a device under test (DUT) having sufficient cross-sectional area and electrical conductivity to complete an electrical connection between the probe and a plurality of contacts in the selected region. The next step of the method involves measuring through the probe a physical property of a device connected to a selected one of the contacts.

### BRIEF DESCRIPTION OF THE DRAWINGS

FIG. 1 is a diagrammatic vertical sectional view of a contactless testing apparatus in accordance with an embodiment of the invention.

FIG. 2 is a simplified diagrammatic vertical sectional view of the contactless testing apparatus of FIG. 1 illustrating the manner in which its probe can establish electrical contact with a plurality of pixel drive circuits of a flat panel display and measure current flow in a transistor of a selected one of the pixel drive circuits that is addressed.

FIG. 3 is a schematic diagram of a pixel drive circuit in an OLED flat panel display.

FIG. 4 is a diagrammatic plan view illustrating of a portion of the layout of the plurality of pixel drive circuits in an OLED flat panel display.

FIG. 5 is a simplified flow diagram illustrating a contactless testing method in accordance with an embodiment of the invention.

FIG. 6 is a simplified diagrammatic vertical sectional view of a DC plasma generator that may be used in an embodiment of the invention.

### DETAILED DESCRIPTION

A contactless test apparatus can be achieved by utilizing an atmospheric pressure plasma jet or plume between a probe and a device under test (DUT). The plasma plume can be in the form of a mass flow of discharge gas carrying with it ions and electrons. The plasma plume must have sufficient electrical conductivity to complete an electrical connection between the probe and the DUT. In one embodiment, a plasma plume generator can take the form of a micro-hollow cathode discharge. See, for example, Sung-Jin Park et al., IEEE Journal on Selected Topics in Quantum Electronics, Vol. 8, No. 1, January/February 2002. The plume generator can be designed so that a cross-sectional area of the plume is sufficient to complete an electrical connection with a plurality of contacts in a selected region of a DUT without moving the plume laterally over the surface of the DUT. Where the contacts connect to circuits that can be independently addressed through switching, such as a display that utilizes thin film transistor (TFT) technology, the circuits can be independently addressed through peripheral leads such as gate and data lines. This allows devices such as particular transistors in the sensitive active area of a display to be tested through the probe in a non-contact manner.

Several advantages are achieved by using a plume of ionized gas to simultaneously make connection with a plurality of individually addressable electrical contacts of a DUT. A probe for establishing a connection with a selected contact of a DUT need not be miniaturized to the size of an individual contact, which may be impractical. Tolerance limitations on X-Y positioning of such a probe are alleviated. Various technologies for generating an electrically conductive plume may be utilized, regardless of inherent limitations on their ability to create plumes having relatively small cross-sectional area. Key components and other devices of a DUT, such as transistors of an organic light emitting diode (OLED) flat panel display, can be tested during a critical stage of fabrication in a rapid, reliable manner that does not present any risk of damage to the DUT. The use of special vacuum chambers and electron beam imaging devices is not required.

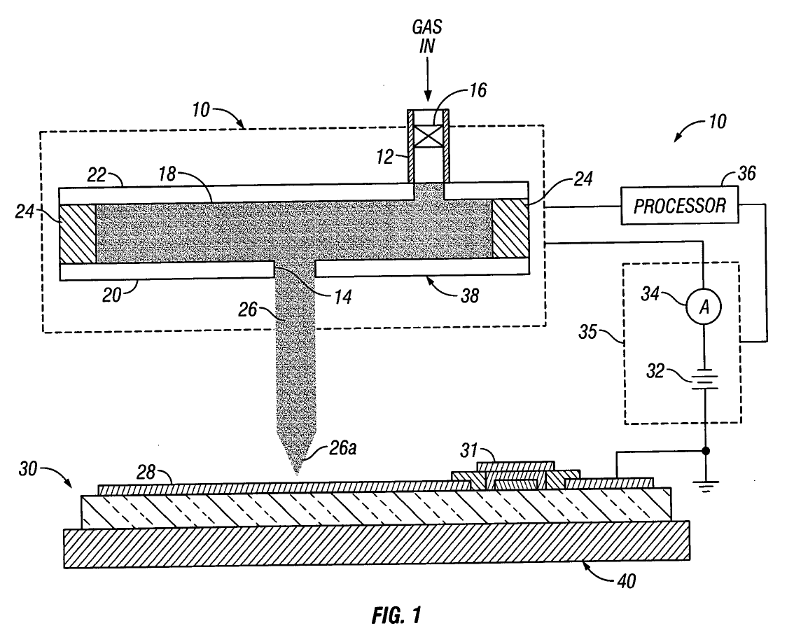

Referring to FIG. 1, Argon gas at above atmospheric pressure, e.g. 48 kPascal to 100 kPascal, enters probe 10 via inlet 12 offset from outlet 14. Valve 16 is used to control the flow of gas into probe 10. The gas initially fills mixing chamber or manifold 18 within probe 10. The gas exits via outlet 14 of micro-hollow cathode 20 into an open environment at, or below, atmospheric pressure. Anode 22 forms the upper wall of manifold 18. Manifold 18 also has side walls 24 that hold cathode 20 and anode 22 in spaced apart relation. Plasma plume 26 carries ions and electrons a distance determined by the gas flow rate and lifetime of the ions and electrons. Plasma plume 26 also contains radicals that are an electrically neutral species that do not contribute to current flow. The location of tapered tip 26a of plume 26 is adjusted so that it touches or comes into close physical proximity with contact 28 of DUT 30. This location adjustment may be made by moving probe 10 along the Z axis, and/or by changing the length of plasma plume 26.

Plasma plume 26 completes an electrical path from contact 28, transistor 31, current source 32 and through meter 34 (or any other sensor) to probe 10. Current source 32 and meter 34 form an external testing circuit 35. Processor 36 controls both the application of current as well as the generation of plasma plume 26 such that the plasma and any signals carried thereby can be precisely controlled. Suitable constructions for plasma plume generator 38 inside probe 10 include metal/dielectric/metal, metal/polymer/metal and metal/semiconductor/metal. Exemplary metals include Au, Ti and Cu. Exemplary dielectrics include sapphire and ceramic. Exemplary polymers include KAPTON® and RT Duriod (PTFE). DUT 30 is supported on test bed 40. The strike voltage necessary to create plasma plume 26 depends on the gas and the type and thickness of dielectric, which would be used for side walls 24 in the embodiment of FIG. 1. By way of example, the strike voltage between cathode 20 and anode 22 could be in the range of 500-700 volts. The internal dimension of manifold 18 can be reduced to the diameter of outlet 14 in which case manifold 18 would essentially be a tube. This may also have the beneficial effect of reducing turbulence as the ionized gas exits outlet 14.

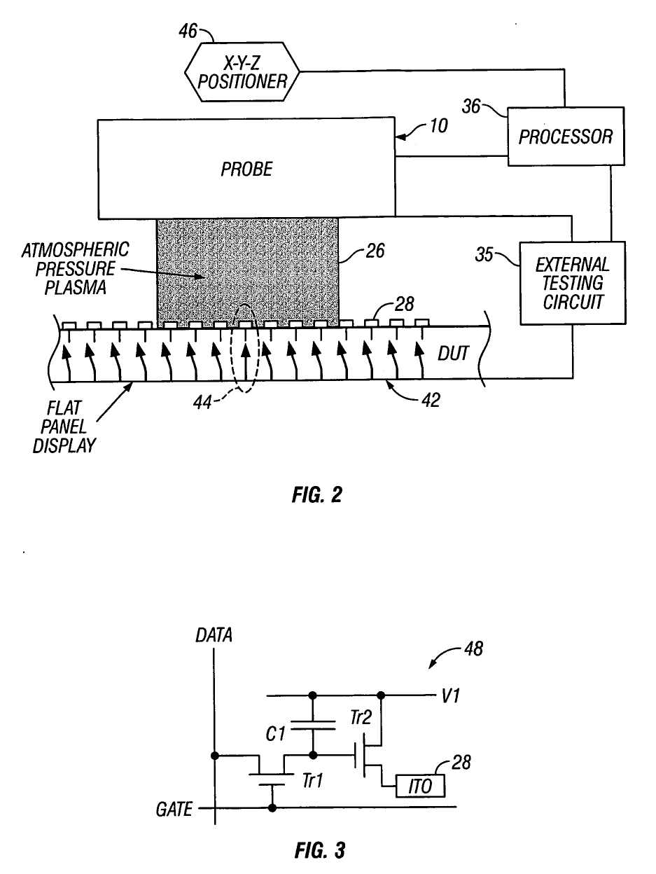

FIG. 2 is a simplified diagrammatic vertical sectional view illustrating the use of probe 10, external testing circuit 35 and processor 36 to measure one or more parameters of a DUT in the form of organic light emitting diode (OLED) flat panel display 42. This figure further illustrates the manner in which probe 10 can simultaneously establish electrical contact with a plurality of pixel drive circuits of OLED flat panel display 42. Probe 10, external testing circuit 35 and processor 36 can measure current flow in a transistor 44 of a selected one of the pixel drive circuits as it is independently addressed. Positioner 46 can move probe 10 independently in minute increments along X, Y and Z axes under control of processor 36. The cross-sectional area of plasma plume 26 is larger than the area of contact 28 of a pixel of OLED display 42 so that many transistors of different pixel drive circuits can be sequentially tested without having to move probe 10 laterally, e.g. along the X or Y axes. All that is required is that probe 10 be located so that plasma plume 26 contacts, or is in close proximity with, a selected region of the active area of OLED flat panel display 42 including a plurality of contacts 28. This arrangement substantially reduces or eliminates alignment problems. This is because the X-Y alignment tolerance between probe 10 and a selected pixel can be relatively large, i.e. on the order of the area of probe 10.

FIG. 3 is a schematic diagram of an exemplary pixel drive circuit 48 of OLED flat panel display 42. Transistor Tr1 is used to set the gate bias on transistor Tr2. The flow of current through transistor Tr2 controls the contrast for the pixel. Capacitor C1 maintains the gate bias for the transistor Tr2 once transistor Tr1 is switched OFF. More complex circuits having four or five transistors exist for accomplishing this function, but all have at least one transistor with one disconnect terminal. Pixel drive circuit 48 includes Indium-Tin-Oxide (ITO) contact 28. Plasma plume 26 provides an electrical connection between probe 10 and transistor Tr2 to allow the current flow through transistor Tr2 to be measured.

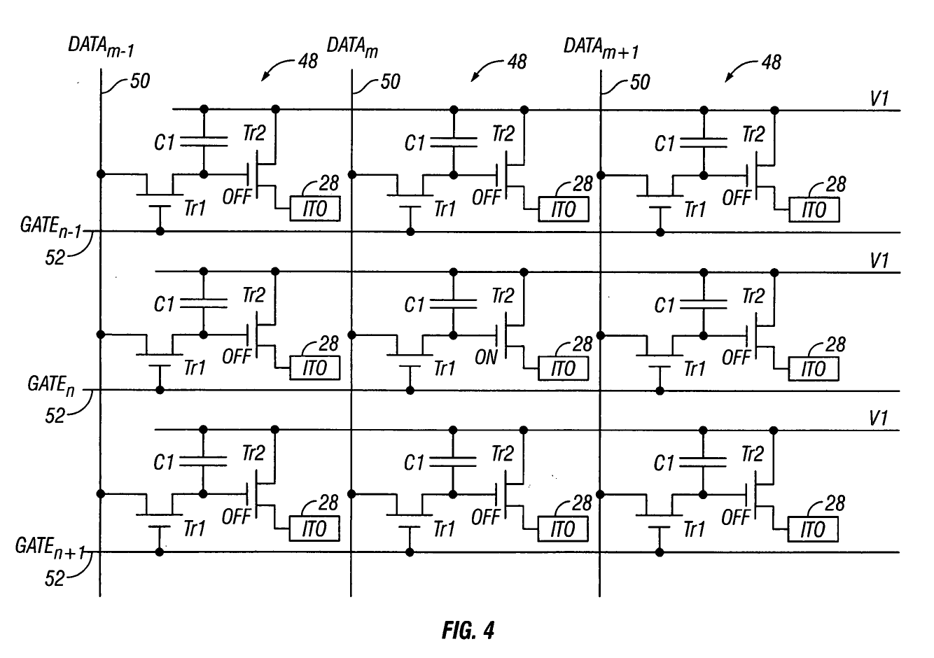

FIG. 4 is a diagrammatic plan view illustrating a portion of the layout of the plurality of pixel drive circuits in OLED flat panel display 42. Data lines 50 and gate lines 52 are used to independently address selected ones of pixel drive circuits 48 through known switching techniques. Each pixel drive circuit 48 in electrical contact with plasma plume 26 is addressed and programmed by charging capacitor C1 such that transistor Tr2 is OFF. Then the selected pixel drive circuit 48 is addressed and testing of transistor Tr2 takes place. Different current levels can be forced through transistor Tr2 for testing its voltage response. A full parametric test is preferred. Thresholds and other parameters can be computed based on the data gathered. Once this process is finished, it is repeated with a different pixel drive circuit 48 being tested.

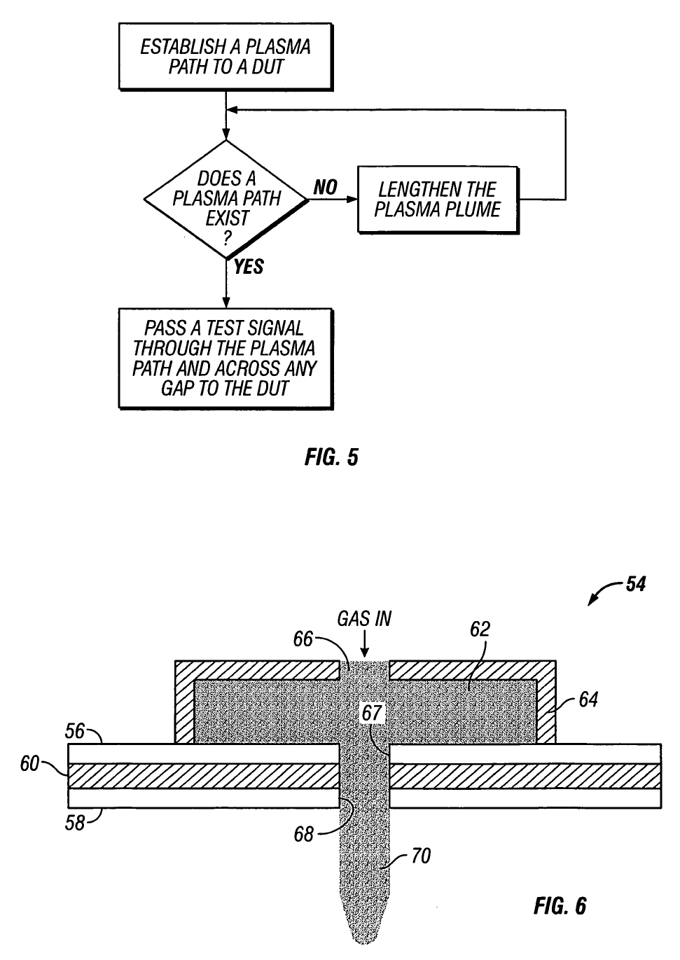

FIG. 5 is a simplified flow diagram illustrating a contactless testing method in accordance with an embodiment of the invention. Initially a plasma plume is generated to establish a contactless electrical path between probe 10 and multiple contacts 28 of DUT 42. External testing circuit 35 and/or processor 36 determine if the plasma path has sufficient electrical conductivity to support measurement of the desired parameters of DUT 42. If not, the length of plume 26 is extended and/or probe 10 is moved closer to DUT 42 along the Z axis. After plume 26 has been optimized, a test signal is passed through plume 26 and across any gap to DUT 42. The test signal is sequentially switched so that if flows through each of contacts 28. The results are recorded and analyzed automatically by processor 36. In broader terms, a contactless testing method in accordance with an embodiment of the invention includes the initial step of generating a plume of ionized gas between a probe and a selected region of a device under test (DUT) having sufficient cross-sectional area and electrical conductivity to complete an electrical connection between the probe and a plurality of contacts in the selected region. The subsequent step of the method involves measuring through the probe a physical property of a device connected to a selected one of the contacts.

Tests of an apparatus of the type described have been conducted that utilize a probe that generates an atmospheric plasma discharge jet that has an exit aperture of approximately fifty microns. The apparatus has been tested on large ITO contacts with currents up to approximately six hundred and sixty micro-amperes. A scanning X-Y stage has been used to increase the area covered by the plasma jet for chemical analysis purposes. Tests have also been conducted on an apparatus of the type described that utilizes a probe that relies upon the principle of photo-ionization. It has an exit aperture of approximately one millimeter in diameter and operates at currents in the range of one to ten micro-amperes. Its geometry allows electrical connection to be simultaneously made with several contacts in the active area of an OLED flat panel display. Hence it is possible to write zeros to the surrounding pixels and a one to the pixel that is being tested. The surrounding devices are turned OFF to form a guard ring. Still further testing is under way on an apparatus of the type described that utilizes a microwave probe that generates plasma in a three hundred micron diameter capillary.

FIG. 6 illustrates a DC plasma generator 54 of the general type currently under test. Anode 56 and cathode 58 are separated by dielectric 60. Manifold 62 is located on top of anode 56 and is defined by insulating material 64. Gas enters orifice 66, fills manifold 62, enters orifice 67 and flows through micro-hollow cathode 68. High density plasma plume 70 is produced at the exit of micro-hollow cathode 68. Very little of the plasma is generated within manifold 62. Anode 56 and cathode 58 can be interchanged since their geometries are symmetrical. The configuration of DC plasma generator 54 facilitates reduction of the diameter of manifold 62 to the diameter of micro-hollow cathode 68 to improve gas flow and reduce turbulence.

The foregoing detailed description sets forth embodiments of a test apparatus and test method particularly suited for testing an organic light emitting diode (OLED) flat panel display. However, those skilled in the art of designing test equipment will appreciate that our invention may be adapted for use with other types of device under test (DUT), including, but not limited to, semiconductor materials, printed circuit boards (PCBs), etc. Moreover, while the embodiments illustrated utilize a plume of atmospheric pressure plasma to make an electrical connection with the DUT without physically contacting the same, other plumes of ionized gas could be utilized having weaker ionization than plasma. In addition, it will be appreciated by those skilled in the art that various forms of ionized gas generators could be used including, but not limited to a DC discharge device, an RF plasma generator, a microwave plasma generator, a corona discharge device, a photo-ionization device, a photo-electron emission device and an electron field emission device. Valves for controlling the supply of gas are not essential. The selected region of the DUT with which the plume makes electrical connection could include only a single contact or it could include multiple contacts. The ionized gas generator could be mounted on the probe or mounted separately from the probe. The DUT could be moved along the X, Y and/or Z axes instead of the plume. The embodiment of the testing apparatus described in detail herein is used to make a simple current measurement. However, the external test circuit is subject to a wide variety of configurations depending upon the nature of the physical property of the DUT that is to be measured. Many different types of signals can be carried by a plume of ionized gas, including signals in the radio frequency (RF) spectrum as well as other frequency ranges. Digital signals can be transmitted over the ionized gas plume. The flow rate of the gas through valve 16 (FIG. 1) can be regulated to produce resonances with different electrical frequencies. Therefore, the protection afforded the invention should only be limited in accordance with the scope of the following claims.

1. A contactless testing apparatus, comprising:
a probe locatable adjacent a selected region of a device under test (DUT), the region having a plurality of contacts; and
a generator capable of establishing a plume of an ionized gas between the probe and the selected region of the DUT having sufficient cross-sectional area and electrical conductivity to complete an electrical connection between the probe and the plurality of contacts.

2. The apparatus of claim 1 wherein the ionized gas is atmospheric pressure plasma.

3. The apparatus of claim 1 wherein the DUT is an organic light emitting diode (OLED) flat panel display having a plurality of contacts each connected to an independently addressable pixel drive circuit.

4. The apparatus of claim 1 and further comprising an external testing circuit connected to the probe for measuring a physical property of a device connected to a selected one of the contacts.

5. The apparatus of claim 1 wherein the generator is mounted on the probe.

6. The apparatus of claim 1 wherein the probe is configured to establish electrical connection with a selected one of the contacts without being re-positioned.

7. The apparatus of claim 3 and further comprising an external testing circuit connected to the probe for measuring a current flow through a transistor of the pixel drive circuit corresponding to a selected pixel.

8. The apparatus of claim 1 wherein a cross-sectional area of the plume is larger than an area of a selected one of the contacts.

9. The apparatus of claim 1 and further comprising a positioner for locating the probe adjacent the selected region of the DUT.

10. The apparatus of claim 1 wherein the generator is selected from the group consisting of a DC discharge device, an RF plasma generator, a microwave plasma generator, a corona discharge device, a photo-ionization device, a photo-electron emission device and an electron field emission device.

11. A contactless testing method, comprising the steps of:
generating a plume of ionized gas between a probe and a selected region of a device under test (DUT) having sufficient cross-sectional area and electrical conductivity to complete an electrical connection between the probe and a plurality of contacts in the selected region; and
measuring through the probe a physical property of a device connected to a selected one of the contacts.

12. The method of claim 11 wherein the plume of ionized gas is generated with a generator selected from the group consisting of a DC discharge device, an RF plasma generator, a microwave plasma generator, a corona discharge device, a photo-ionization device, a photo-electron emission device and an electron field emission device.

13. The method of claim 11 and further comprising the step of positioning the probe adjacent the selected region before measuring the physical property of the device.

14. The method of claim 11 wherein the DUT is an organic light emitting diode (OLED) flat panel display having a plurality of contacts each connected to an independently addressable pixel drive circuit.

15. The method of claim 14 wherein the physical property that is measured is a current flow through a transistor of the pixel drive circuit.

16. The method of claim 11 wherein the plume of ionized gas is atmospheric pressure plasma.

17. The method of claim 11 and further comprising the step of adjusting a length of the plume of ionized gas to complete the electrical connection between the probe and the plurality of contacts in the selected region.

18. The method of claim 11 wherein a cross-sectional area of the plume is larger than an area of one of the contacts.

19. The method of claim 11 wherein a test signal is sequentially switched so that it flows through each of the contacts.

20. The method of claim 13 wherein the positioning is accomplished by moving the probe along X and Y axes.

21. A contactless testing apparatus for an organic light emitting diode (OLED) flat panel display having a plurality of pixels each connected to an independently addressable pixel drive circuit having a contrast controlling transistor, comprising:
a probe;
a positioner for moving the probe adjacent a selected group of contacts in an active area of an OLED flat panel display;
a generator that establishes a plume of ionized gas between the probe and the group of contacts having sufficient cross-sectional area and electrical conductivity to complete an electrical connection between each of the contacts and the probe; and
an external testing circuit connected to the probe for measuring a current flow through a contrast controlling transistor of a pixel drive circuit connected to a selected one of the contacts.

22. A contactless method of testing an OLED flat panel display, comprising the steps of:
positioning a probe adjacent a selected region of an organic light emitting diode (OLED) flat panel display, the selected region containing a plurality of contacts each connected to a contrast controlling transistor of a corresponding pixel drive circuit;
generating a plume of atmospheric plasma between the probe and the selected region of the OLED flat panel display having sufficient cross-sectional area and electrical conductivity to complete an electrical connection between the probe and the contacts;
addressing a selected pixel drive circuit; and
measuring a flow of current through the contrast controlling transistor of the selected pixel drive circuit through the probe.
